(19) United States
(12) Patent Application Publication
(10) Pub. No.: US 2018/0123546 A1
(43) Pub. Date: May 3, 2018

(54) IN-VEHICLE MOTOR-DRIVEN COMPRESSOR

(71) Applicant: KABUSHIKI KAISHA TOYOTA JIDOSHOKKI, Kariya-shi (JP)

(72) Inventors: Fumihiro KAGAWA, Kariya-shi (JP); Shunsuke AMBO, Kariya-shi (JP); Yoshiki NAGATA, Kariya-shi (JP)

(73) Assignee: KABUSHIKI KAISHA TOYOTA JIDOSHOKKI, Kariya-shi (JP)

(21) Appl. No.: 15/787,824

(22) Filed: Oct. 19, 2017

(30) Foreign Application Priority Data
Oct. 31, 2016 (JP) 2016-213033

(51) Int. Cl. H03H 7/01; H02P 27/06; H01F 27/24; H01F 27/28; F04B 17/03

(52) U.S. Cl. CPC H03H 7/0115; H02P 27/06; F04B 17/03; H01F 27/28; H01F 27/24

(57) ABSTRACT

An in-vehicle motor-driven compressor includes a housing, a compression portion, an electric motor, and an inverter device. The inverter device includes a low-pass filter circuit, which reduces normal-mode noise included in DC power, and an inverter circuit, which converts the DC power into AC power. The low-pass filter circuit includes a normal-mode coil, which includes a pillar-shaped core extending in one direction and a winding wound around the core and forms an open magnetic circuit. The core includes two end faces in a direction in which the core extends. The inverter device includes a damping portion. The damping portion is arranged at a position where the damping portion is opposed to at least one of the two end faces of the core and an eddy current is generated by magnetic force lines produced in the normal-mode coil.

### BACKGROUND OF THE INVENTION

The present invention relates to an in-vehicle motor-driven compressor.

Conventionally, in-vehicle motor-driven compressors have been known that include a compression portion, an electric motor for driving the compression portion, and an inverter device for driving the electric motor (for example, see Japanese Patent No. 5039515).

The DC power to be converted by the inverter device may include normal-mode noise. In this case, the normal-mode noise may hinder the normal power conversion by the inverter device. This can hamper the operation of the in-vehicle motor-driven compressor.

In particular, the frequency of the normal-mode noise varies according to the type of vehicle on which the in-vehicle motor-driven compressor is mounted. Therefore, to make an in-vehicle motor-driven compressor have the versatility of being applicable to a wide variety of types of vehicles, the compressor is desired to be capable of reducing the normal-mode noise in a wide frequency band. Nonetheless, the size of an in-vehicle motor-driven compressor is preferably prevented from being increased since it is mounted in a vehicle.

### SUMMARY OF THE INVENTION

Accordingly, it is an objective of the present invention to provide an in-vehicle motor-driven compressor that is capable of reducing the normal-mode noise included in DC power in a favorable manner.

To achieve the foregoing objective and in accordance with one aspect of the present invention, an in-vehicle motor-driven compressor is provided that includes a housing, into which a fluid is drawn, a compression portion, which is accommodated in the housing and compresses the fluid, an electric motor, which drives the compression portion, and an inverter device, which drives the electric motor and converts DC power into AC power. The inverter device includes a low-pass filter circuit, which is configured to reduce normal-mode noise included in the DC power, and an inverter circuit, which converts the DC power, of which the normal-mode noise has been reduced by the low-pass filter circuit, into the AC power. The low-pass filter circuit includes a normal-mode coil, which includes a pillar-shaped core extending in one direction and a winding wound around the core and forms an open magnetic circuit. The core has two end faces in an extension direction of the core. The inverter device includes a damping portion. The damping portion is arranged at a position where the damping portion is opposed to at least one of the two end faces of the core and an eddy current is generated by magnetic force lines produced in the normal-mode coil.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a partially cut away diagram schematically showing the outline of an in-vehicle motor-driven compressor and an in-vehicle air conditioner;

FIG. 2 is an exploded perspective view schematically showing a structure for noise reduction;

FIG. 3 is a cross-sectional view schematically showing the structure for noise reduction;

FIG. 4 is a cross-sectional view taken along line 4-4 of FIG. 3;

FIG. 5 is an equivalent circuit diagram showing the electrical configuration of the in-vehicle motor-driven compressor;

FIG. 6 is a graph showing the frequency characteristics of a low-pass filter circuit in relation to normal-mode noise;

FIG. 7 is a cross-sectional view schematically showing a damping portion of a modification; and

FIG. 8 is a cross-sectional view schematically showing a damping portion of another modification.

### DETAILED DESCRIPTION OF THE PREFERRED EMBODIMENTS

An in-vehicle motor-driven compressor according to one embodiment will now be described. The in-vehicle motor-driven compressor of the present embodiment is used in an in-vehicle air conditioner. That is, the fluid to be compressed in the in-vehicle motor-driven compressor in the present embodiment is refrigerant.

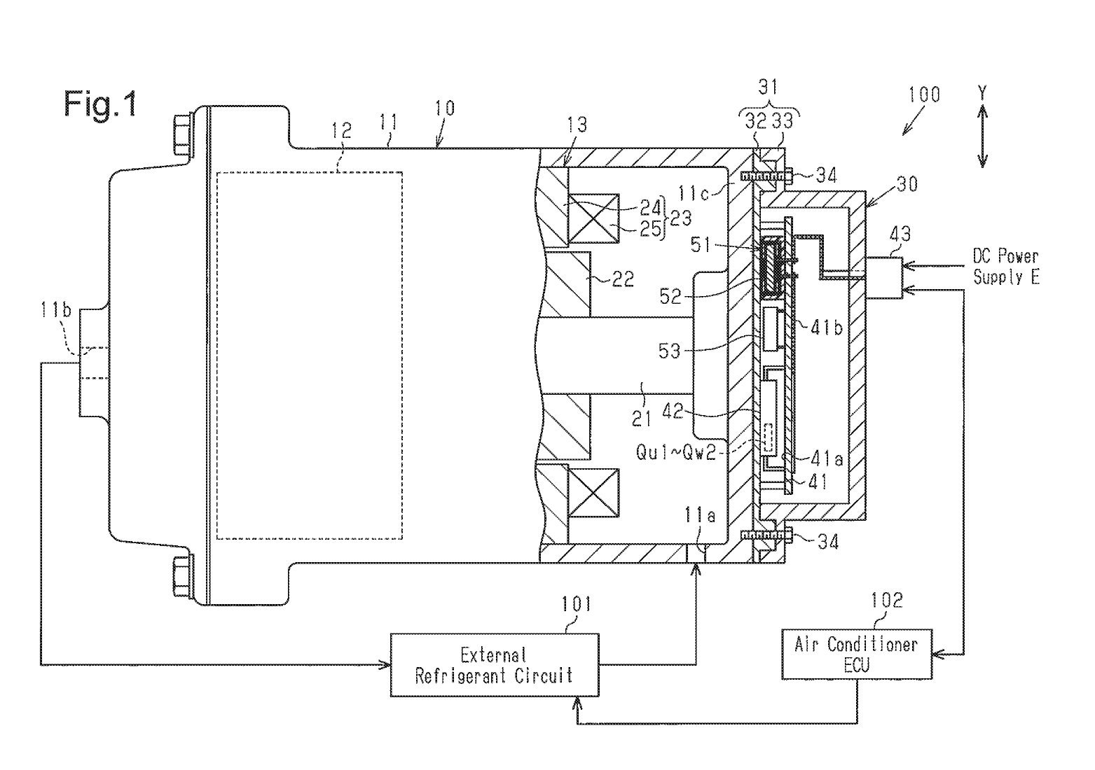

As shown in FIG. 1, the in-vehicle air conditioner 100 includes the in-vehicle motor-driven compressor 10 and an external refrigerant circuit 101. The external refrigerant circuit 101 supplies refrigerant, which is a fluid, to the in-vehicle motor-driven compressor 10. The external refrigerant circuit 101 includes, for example, a heat exchanger and an expansion valve. The in-vehicle motor-driven compressor 10 compresses the refrigerant, and the external refrigerant circuit 101 performs the heat exchange of the refrigerant and expands the refrigerant. This allows the in-vehicle air conditioner 100 to cool or warm the passenger compartment.

The in-vehicle air conditioner 100 includes an air conditioner ECU 102, which controls the entire in-vehicle air conditioner 100. The air conditioner ECU 102 is configured to obtain parameters such as the temperature of the passenger compartment and a target temperature. Based on the parameters, the air conditioner ECU 102 outputs various commands such as an ON-OFF command to the in-vehicle motor-driven compressor 10.

The in-vehicle motor-driven compressor 10 includes a housing 11, a compression portion 12, and an electric motor 13. The housing 11 has an inlet 11a, into which the refrigerant from the external refrigerant circuit 101 is drawn. The compression portion 12 and the electric motor 13 are accommodated in the housing 11.

The housing 11 is substantially cylindrical as a whole and made of a thermally conductive material (for example, a metal such as aluminum). The housing 11 has an outlet, through which refrigerant is discharged. The housing 11 is grounded to the body of the vehicle.

When a rotary shaft 21, which will be discussed below, rotates, the compression portion 12 compresses the refrigerant that has been drawn into the housing 11 through the inlet 11a and discharges the compressed refrigerant through the outlet 11b. The compression portion 12 may be any type such as a scroll type, a piston type, or a vane type.

The electric motor 13 drives the compression portion 12. The electric motor 13 includes the columnar rotary shaft 21, which is rotationally supported, for example, by the housing 11, a cylindrical rotor 22, which is fixed to the rotary shaft 21, and a stator 23 fixed to the housing 11. The axial direction of the rotary shaft 21 coincides with the axial direction of the cylindrical housing 11. The stator 23 includes a cylindrical stator core 24 and coils 25 wound about the teeth of the stator core 24. The rotor 22 and the stator 23 face each other in the radial direction of the rotary shaft 21. When the coils 25 are supplied with currents, the rotor 22 and the rotary shaft 21 rotate. Accordingly, the compression portion 12 compresses refrigerant.

As shown in FIG. 1, the in-vehicle motor-driven compressor 10 includes an inverter device 30, which drives the electric motor 13.

The inverter device 30 includes an inverter case 31, which accommodates various types of components such as a circuit board 41, a power module 42, and a low-pass filter circuit 51. The inverter case 31 is made of a nonmagnetic and thermally conductive material (for example, a metal such as aluminum).

The housing 11 includes a mounting wall portion 11c, which is one of the wall portions on the opposite sides in the axial direction. The mounting wall portion 11c is located on the side opposite from the outlet 11b. The inverter case 31 includes a base member 32 and a cylindrical cover member 33. The base member 32 contacts the mounting wall portion 11c. The cover member 33 has a closed end and is assembled to the base member 32. The base member 32 and the cover member 33 are fixed to the housing 11 with bolts 34, which serve as fasteners. Thus, the inverter device 30 is attached to the housing 11. That is, the inverter device 30 of the present embodiment is integrated with the in-vehicle motor-driven compressor 10.

Since the inverter case 31 and the housing 11 contact each other, these are thermally coupled to each other. The inverter device 30 is arranged at a position where the inverter device 30 is thermally coupled to the housing 11. The inverter case 31 is configured not to allow refrigerant to flow directly thereinto.

The mounting wall portion 11c of the housing 11, to which the inverter case 31 is attached, is arranged on the opposite side of the electric motor 13 from the compression portion 12. In this respect, it can be said that the inverter case 31 is arranged on the opposite side of the electric motor 13 from the compression portion 12. The compression portion 12, the electric motor 13, and the inverter device 30 are arranged along the axis of the rotary shaft 21. That is, the in-vehicle motor-driven compressor 10 of the present embodiment is a so-called inline type.

The inverter device 30 includes, for example, a circuit board 41 fixed to the base member 32, and the power module 42 mounted on the circuit board 41. The circuit board 41 is arranged to be opposed to the base member 32 at a predetermined distance in the axial direction of the rotary shaft 21 and has a board surface 41a opposed to the base member 32. The board surface 41a is the surface on which the power module 42 is mounted.

The output side of the power module 42 is electrically connected to the coils 25 of the electric motor 13 via hermetic terminals (not shown) provided in the mounting wall portion 11c of the housing 11. The power module 42 includes switching element Qu1, Qu2, Qv1, Qv2, Qw1, Qw2.

The inverter case 31 has a connector 43. Specifically, the connector 43 is provided on the cover member 33. The DC power supply E mounted on the vehicle supplies DC power to the inverter device 30 via the connector 43, and the air conditioner ECU 102 and the inverter device 30 are electrically connected via the connector 43.

The connector 43 and the input side of the power module 42 are electrically connected to each other. In a state in which DC power is being supplied to the power module 42 via the connector 43, the switching elements Qu1 to Qw2 are periodically turned on and off, so that the inverter device 30 converts the DC power into AC power and delivers the AC power to the coils 25 of the electric motor 13. This drives the electric motor 13.

The current (in other words, the power) handled by the inverter device 30 has a magnitude sufficient for driving the electric motor 13 and is greater than the current (in other words, the power) of signals. The DC power supply E is, for example, an in-vehicle electric storage device such as a rechargeable battery or a capacitor.

As shown in FIG. 1, the circuit board 41 has patterned traces 41b. The patterned traces 41b are used for the electrical connections between the power module 42 and the low-pass filter circuit 51 and for the electrical connections between the low-pass filter circuit 51 and the connector 43. The patterned traces 41b are provided, for example, on the surface opposite to the board surface 41a. However, the present invention is not limited to this, and the patterned traces 41b may be provided on the board surface 41a, or may be formed on both the board surface 41a and the surface opposite to the board surface 41a. Further, the patterned traces 41b may be formed in multiple layers in the circuit board 41. The specific structure of the patterned traces 41b is arbitrary, and may be, for example, bar-shaped like a bus bar or flat plate-shaped.

The DC power transmitted from the connector 43 to the power module 42 may include normal-mode noise. The normal-mode noise can also be regarded as an inflowing ripple component contained in the DC power flowing into the inverter device 30. The details of the normal-mode noise will be discussed below.

In this respect, the inverter device 30 of the present embodiment includes the low-pass filter circuit 51, which reduces, or attenuates, the normal-mode noise included in the DC power transmitted from the connector 43 to the power module 42. The DC power transmitted from the connector 43 to the power module 42 is, in other words, the DC power delivered to the inverter device 30. The low-pass filter circuit 51 is provided on the power transmission path from the connector 43 to the power module 42, so that the DC power supplied from the connector 43 is delivered to the power module 42 through the low-pass filter circuit 51.

The low-pass filter circuit 51 has a normal-mode coil 52 and a capacitor 53, which is electrically connected to the normal-mode coil 52. The normal-mode coil 52 and the capacitor 53 are arranged, for example, between the circuit board 41 and the housing 11, specifically, between the circuit board 41 and the base member 32.

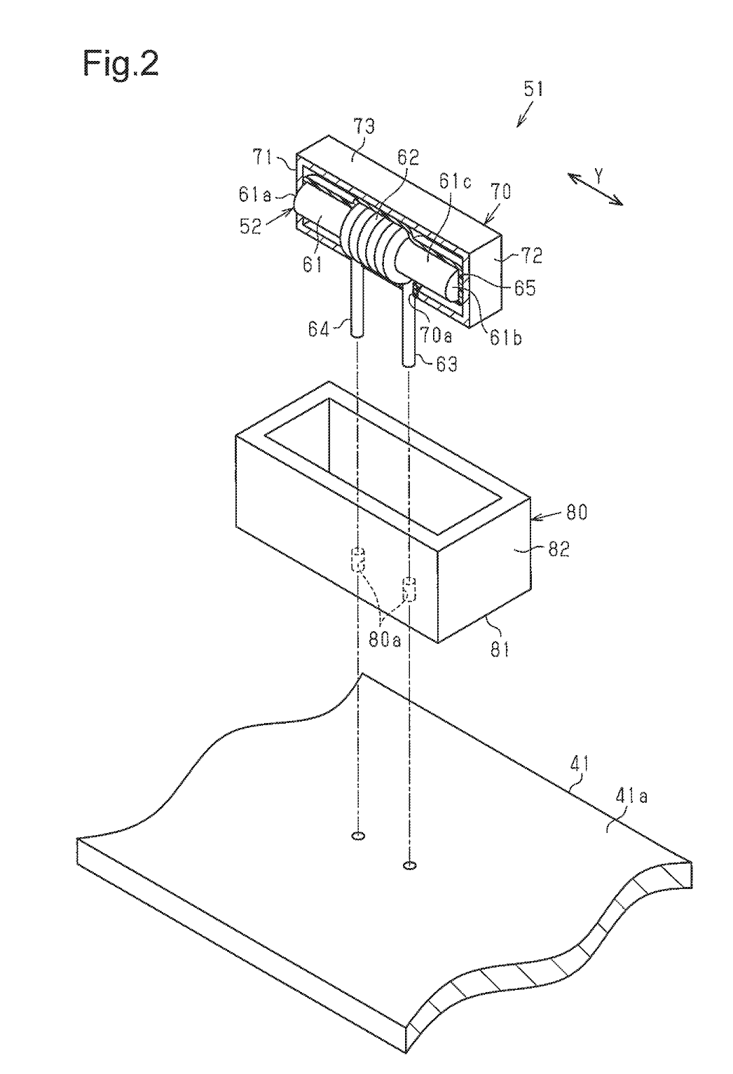

As shown in FIGS. 2 to 4, the normal-mode coil 52 has a core 61, a winding 62 wound around the core 61, and terminals 63, 64 drawn out from the winding 62.

The core 61 is shaped as a pillar extending in one direction. In the present embodiment, the core 61 is columnar and has a side surface 61c and two end faces 61a, 61b in the extension direction. The extension direction Y is, in other words, the axial direction of the core 61. The end faces 61a, 61b are circular, and the side surface 61c extends in the extension direction Y and the circumferential direction. That is, the side surface 61c is the circumferential surface of the core 61.

The extension direction Y of the core 61 intersects, or specifically is perpendicular to an opposing direction, in which the circuit board 41 and the base member 32 are opposed to each other. The opposing direction can also be regarded as the direction in which the circuit board 41 and the housing 11 (specifically the mounting wall portion 11c) are opposed to each other. The extension direction Y is parallel to the board surface 41a.

In the present embodiment, the core 61 is configured by a single part. However, the present invention is not limited to this, and the core 61 may be configured, for example, by coupling multiple parts.

The winding 62 is spirally wound around the side surface 61c of the core 61. The axial direction of the winding 62 coincides with the extension direction Y.

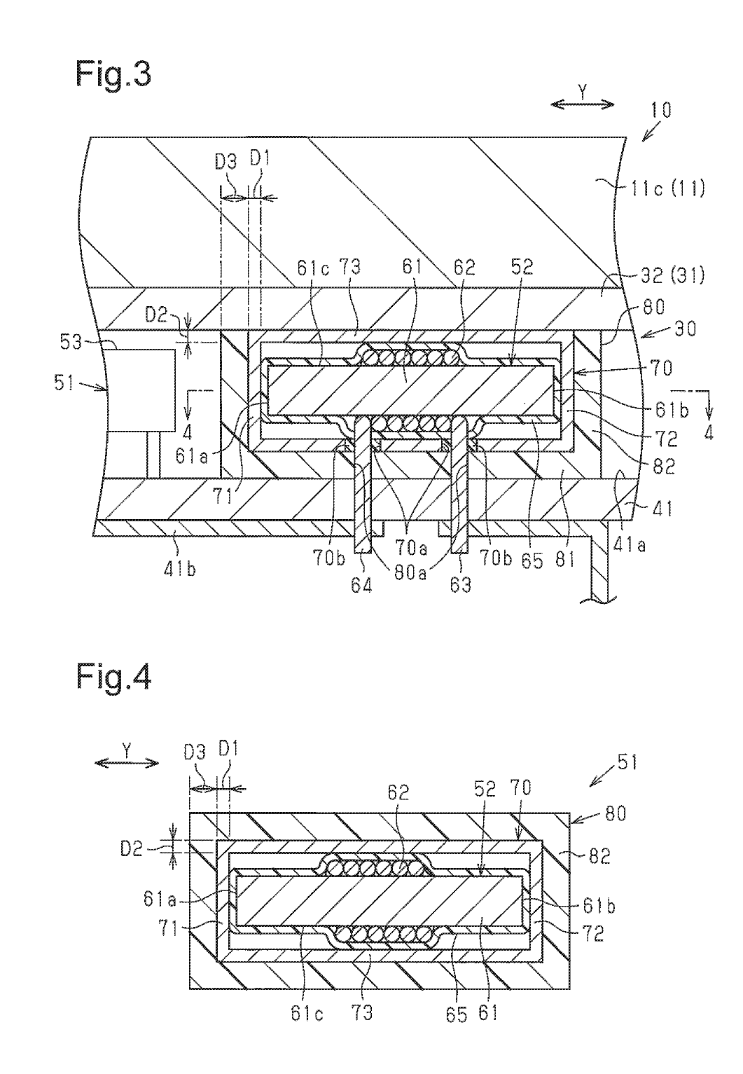

As shown in FIGS. 2 and 3, the terminals 63, 64 extend toward the circuit board 41 and are electrically connected to the patterned traces 41b while extending through the circuit board 41. The input terminal 63 of the terminals 63, 64 is connected to the positive terminal of the DC power supply E via the connector 43, and the output terminal 64 is connected to the power module 42 via the patterned traces 41b. The terminals 63, 64 can also be regarded as the ends of the winding 62.

This configuration receives DC power via the connector 43, so that current flows through the winding 62. In this case, an open magnetic circuit is formed around the normal-mode coil 52. The open magnetic circuit has an oval shape connecting the end faces 61a, 61b in the extension direction Y. That is, the normal-mode coil 52 is an open magnetic circuit type forming an open magnetic circuit. In other words, the core 61 has a pillar shape extended in one direction so as to form an open magnetic circuit. In this case, magnetic flux tends to concentrate near the end faces 61a, 61b.

The capacitor 53 is constituted, for example, by a film capacitor or an electrolytic capacitor. The capacitor 53 is electrically connected to the normal-mode coil 52 via the patterned traces 41b and cooperates with the normal-mode coil 52 to constitute the low-pass filter circuit 51. The low-pass filter circuit 51 reduces the normal-mode noise flowing in from the DC power supply E. The low-pass filter circuit 51 is a resonance circuit and can also be regarded as an LC filter.

In the present embodiment, the capacitor 53 and the normal-mode coil 52 are arranged side by side in the extension direction Y. However, the present invention is not limited to this and the concrete arrangement of the capacitor 53 and the normal-mode coil 52 is arbitrary.

As shown in FIGS. 2 to 4, the inverter device 30 has an insulating portion 65 covering the normal-mode coil 52. The insulating portion 65 is composed of, for example, an insulating film, and covers the entire core 61 and winding 62. The insulating portion 65 is in contact with the core 61 and the winding 62.

The inverter device 30 includes a damping portion 70, which covers both the normal-mode coil 52 and the insulating portion 65, and an insulating accommodation case 80, which accommodates the normal-mode coil 52 and the damping portion 70.

The damping portion 70 is provided at a position where an eddy current is generated by magnetic force lines produced in the normal-mode coil 52. The damping portion 70 is configured to reduce the Q-value of the low-pass filter circuit 51 with a generated eddy current. That is, the damping portion 70 lowers the Q-value of the low-pass filter circuit 51 by generating an eddy current with magnetic flux (magnetic force lines) passing through the open magnetic circuit of the normal-mode coil 52.

The damping portion 70 is made of a nonmagnetic and conductive material such as aluminum. The relative magnetic permeability of the damping portion 70 is preferably set to, for example, 0.9 to 3.

The damping portion 70 is provided at a position opposed to at least one of the end faces 61a, 61b in the extension direction Y of the core 61. In the present embodiment, the damping portion 70 is provided at a position opposed to both of the end faces 61a, 61b in the extension direction Y of the core 61. More specifically, the damping portion 70 has a pair of end face covering portions 71, 72, which are provided at positions opposed to the end faces 61a, 61b in the extension direction Y of the core 61. For example, the end face covering portions 71, 72 are slightly larger than the end faces 61a, 61b and are shaped as plates having the thickness direction that coincides with the extension direction Y. In the present embodiment, the end face covering portions 71, 72 are shaped as rectangular plates. The end face covering portions 71, 72 are arranged to be opposed to each other in the extension direction Y. That is, the end face covering portions 71, 72 are arranged so that the thickness direction of the end face covering portions 71, 72 coincides with the extension direction Y of the core 61.

The damping portion 70 has a side surface covering portion 73, which covers at least part of the side surface 61c of the core 61 and connects the end face covering portions 71, 72 to each other. The side surface covering portion 73 is provided at a position opposed to the side surface 61c of the core in the radial direction of the core 61. The side surface covering portion 73 of the present embodiment is a rectangular tubular wall portion that is slightly larger than the side surface 61c of the core 61 and covers the entire side surface 61c of the core 61. The side surface covering portion 73 has a rectangular frame shape when viewed from the extension direction Y.

That is, the damping portion 70 of the present embodiment has a rectangular parallelepiped shape covering both the normal-mode coil 52 and the insulating portion 65. FIG. 2 illustrates only half of the damping portion 70. The insulating portion 65 is provided between the normal-mode coil 52 and the damping portion 70.

As shown in FIG. 3, the thickness D1 of the end face covering portions 71, 72 is constant in the present embodiment. The thickness D1 of the end face covering portions 71, 72 is greater than the thickness of the insulating portion 65 and less than the thickness of the housing 11. In particular, the thickness D1 of the end face covering portions 71, 72 is less than the thickness of the mounting wall portion 11c. The thickness D1 of the end face covering portions 71, 72 can also be regarded as the dimension in the extension direction Y.

In the present embodiment, the thickness (the frame width) D2 of the side surface covering portion 73 is constant regardless of the location. The thickness D1 of the end face covering portions 71, 72 is the same as the thickness D2 of the side surface covering portion 73. The thickness D2 of the side surface covering portion 73 can also be regarded as the difference between the inner dimension and the outer dimension of the side surface covering portion 73.

As shown in FIGS. 3 and 4, in the present embodiment, the end face covering portions 71, 72 is in contact with the part of the insulating portion 65 that covers the end faces 61a, 61b in the extension portion Y, and the side surface covering portion 73 is in contact with the part of the insulating portion 65 that covers the winding 62. The part of the side surface covering portion 73 adjacent to the base member 32 is in contact with the base member 32.

With this configuration, the magnetic force lines produced in the normal-mode coil 52 pass through the damping portion 70. As a result, an eddy current is generated in the damping portion 70, and the eddy current hampers the flow of the magnetic flux passing through the open magnetic circuit of the normal-mode coil 52. This reduces the magnetic flux. That is, the damping portion 70 functions as magnetic reluctance against the magnetic flux generated from the normal-mode coil 52.

Since the insulating portion 65 is arranged between the normal-mode coil 52 and the damping portion 70, the normal-mode coil 52 is insulated from the damping portion 70. This prevents these two from being short-circuited.

The heat generated in the normal-mode coil 52, in particular, the heat generated in the core 61 and the winding 62, is transferred to the damping portion 70 via the insulating portion 65. The heat transferred to the damping portion 70 is then transferred to the housing 11 (the mounting wall portion 11c) via the base member 32. The normal-mode coil 52 is thus cooled.

As shown in FIGS. 2 and 3, the accommodation case 80 has a box shape having an opening adjacent to the base member 32. Specifically, the accommodation case 80 has a rectangular plate-shaped bottom portion 81 and an upright wall portion 82 extending upright toward the mounting wall portion 11c from the periphery of the bottom portion 81. The upright wall portion 82 is shaped as a rectangular frame. The upright wall portion 82 and the end face covering portions 71, 72 are opposed to each other. The accommodation case 80 is attached to the circuit board 41.

The normal-mode coil 52, the insulating portion 65, and the damping portion 70 are accommodated in the accommodation case 80 in a state in which the relative positions are restrained from being changed. Specifically, the unitized body of the normal-mode coil 52, the insulating portion 65, and the damping portion 70 is fitted into the accommodation case 80. In other words, the accommodation case 80 accommodates the normal-mode coil 52 and the damping portion 70 while restricting changes in the relative positions of the normal-mode coil 52 and the damping portion 70.

The outer surface of the damping portion 70 except for the surface adjacent to the base member 32 is in contact with the inner surface of the accommodation case 80. The open end face of the accommodation case 80, in particular, the distal end face of the upright wall portion 82, is flush with the surface of the damping portion 70 that is adjacent to the base member 32 and is in contact with the base member 32.

The accommodation case 80 is made of an insulating material such as plastic so as not to short-circuit with the damping portion 70. For this reason, an eddy current is unlikely to occur in the accommodation case 80.

As shown in FIGS. 3 and 4, the thickness D1 of the end face covering portions 71, 72 is less than the thickness D3 of the upright wall portion 82 in the present embodiment. However, the thickness D1 of the end face covering portions 71, 72 may be greater than or equal to the thickness D3 of the upright wall portion 82.

As shown in FIG. 3, the damping portion 70 has through-holes 70a, through which the terminals 63, 64 of the normal-mode coil 52 can be inserted. The through-holes 70a are formed in part of the side surface covering portion 73 that is closer to the circuit board 41 than to the base member 32 and extend in the radial direction of the core 61. An insulating layer 70b is formed on the inner surface of each through-hole 70a. The accommodation case 80 has communication holes 80a in the bottom portion 81 that communicate with the through-holes 70a and are configured to receive the terminals 63, 64. When received in the through-holes 70a and the communication holes 80a, the terminals 63, 64 reach the circuit board 41 and are electrically connected to the patterned traces 41b in this state. This electrically connects the winding 62 and the patterned traces 41b to each other, while preventing the damping portion 70 and the terminals 63, 64 from being short-circuited.

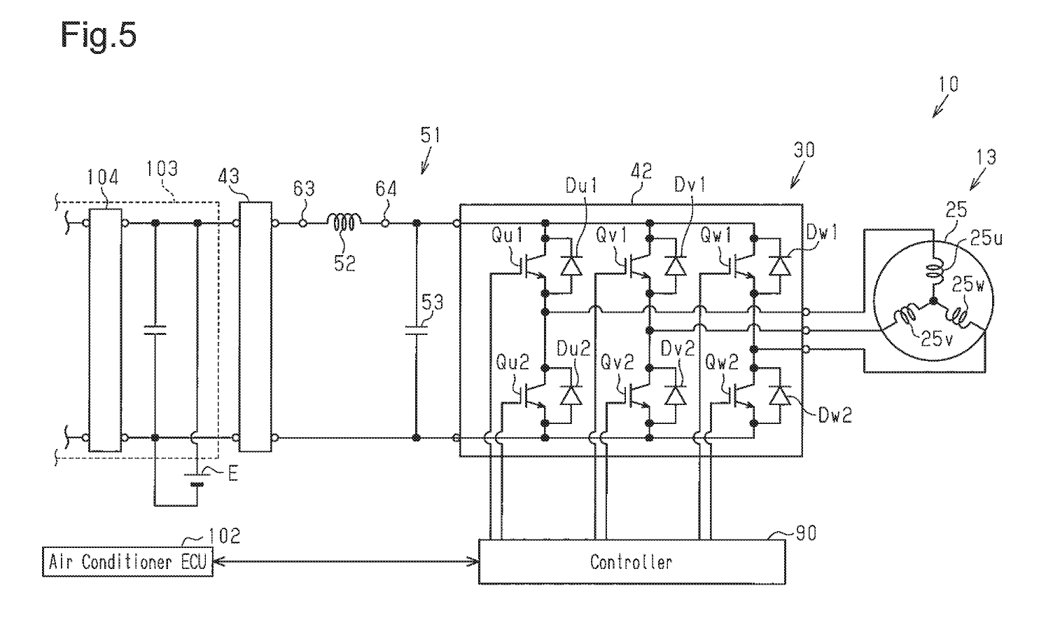

Next, the electrical configuration of the in-vehicle motor-driven compressor 10 will be described with reference to FIG. 5.

As described above, the low-pass filter circuit 51 is provided on the input side of the power module 42 (specifically, the switching elements Qu1 to Qw2). Specifically, the low-pass filter circuit 51 is arranged between the connector 43 and the power module 42.

The normal-mode coil 52 is provided on one of the two wires that electrically connect the connector 43 and the power module 42 to each other. The capacitor 53 is provided on the output side of the normal-mode coil 52 and on the input side of the power module 42. More specifically, one end of the capacitor 53 is connected to the wire connecting the output terminal 64 of the normal-mode coil 52 and the power module 42, and the other end of the capacitor 53 is connected to the wire connecting the connector 43 and the power module 42. Although not shown, the damping portion 70 has a function of lowering the Q-value of the low-pass filter circuit 51.

As shown in FIG. 5, the vehicle is equipped with, for example, a power control unit (PCU) 103 as an in-vehicle device that is provided independently from the inverter device 30. The PCU 103 uses the DC power from the DC power supply E to drive the vehicle-driving motor. That is, in the present embodiment, the PCU 103 and the inverter device 30 are connected in parallel with the DC power supply E. The DC power supply E is shared by the PCU 103 and the inverter device 30.

The PCU 103 has, for example, a boost converter 104 and a vehicle-driving inverter (not shown). The boost converter 104 includes a boost switching element and periodically turns the boost switching element on and off to boost the DC power of the DC power supply E. The vehicle-driving inverter converts the DC power boosted by the boost converter 104 to drive power capable of driving the vehicle-driving motor.

In the above described configuration, the noise generated by switching actions of the boost switching element flows into the inverter device 30 as normal-mode noise. In other words, the normal-mode noise contains a noise component corresponding to the switching frequency of the boost switching element. Since the switching frequency of the boost switching element varies depending on the vehicle type, the frequency of the normal-mode noise varies depending on the vehicle type. The noise component corresponding to the switching frequency of the boost switching element can contain not only a noise component having the same frequency as the switching frequency, but also its harmonic components.

With this configuration, the normal-mode noise included in the DC power supplied to the inverter device 30 is reduced by the low-pass filter circuit 51, and the DC power with the reduced normal-mode noise is delivered to the power module 42.

As shown in FIG. 5, the coils 25 of the electric motor 13 are of a three-phase structure, for example, with a u-phase coil 25u, a v-phase coil 25v, and a w-phase coil 25w. The coils 25u to 25w are connected in a Y-connection.

The power module 42 is an inverter circuit. The power module 42 includes u-phase switching elements Qu1, Qu2 corresponding to the u-phase coil 25u, v-phase switching elements Qv1, Qv2 corresponding to the v-phase coil 25v, and w-phase switching elements Qw1, Qw2 corresponding to the w-phase coil 25w. Each of the switching elements Qu1 to Qw2 is, for example, a power switching element such as an IGBT. The switching elements Qu1 to Qw2 include freewheeling diodes (body diodes) Du1 to Dw2.

The u-phase switching elements Qu1, Qu2 are connected to each other in series by a connection wire that is connected to the u-phase coil 25u. The DC power is delivered to the serially-connected body of the u-phase switching elements Qu1 and Qu2.

Except for the corresponding coils, the other switching elements Qv1, Qv2, Qw1, Qw2 have the same connection structure as the u-phase switching elements Qu1, Qu2.

The inverter device 30 includes a controller 90, which controls the power module 42 (specifically, switching of the switching elements Qu1 to Qw2). Specifically, the controller 90 controls the switching operation of each of the switching elements Qu1 to Qw2. The controller 90 is electrically connected to the air conditioner ECU 102. Based on commands from the air conditioner ECU 102, the controller 90 periodically turns the switching elements Qu1 to Qw2 on and off. Specifically, based on commands from the air conditioner ECU 102, the controller 90 performs pulse width modulation control (PWM control) on the switching elements Qu1 to Qw2. More specifically, the controller 90 uses a carrier signal and a commanded voltage value signal (signal for comparison) to generate control signals. The controller 90 executes ON-OFF control on the switching elements Qu1 to Qw2 by using the generated control signal, thereby converting the DC power, in which the normal-mode noise has been reduced by the low-pass filter circuit 51, into AC power.

The cutoff frequency fc of the low-pass filter circuit 51 is set to be lower than the carrier frequency f1, which is the frequency of the carrier signal. The carrier frequency f1 can also be regarded as the switching frequency of each of the switching elements Qu1 to Qw2.

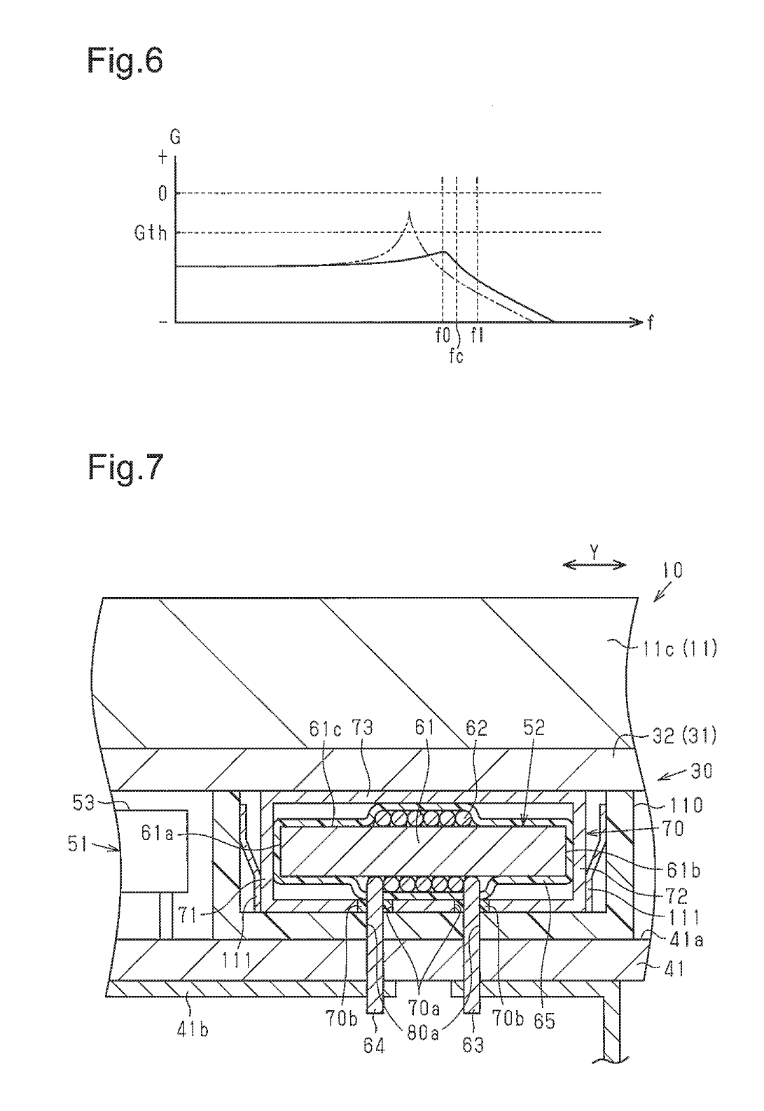

Next, the frequency characteristics of the low-pass filter circuit 51 of the present embodiment will be described with reference to FIG. 6. FIG. 6 is a graph showing the frequency characteristics of the low-pass filter circuit 51 in relation to the flowing-in normal-mode noise. The solid line in FIG. 6 represents the frequency characteristics when the damping portion 70 is present, and the long dashed double-short dashed line in FIG. 6 represents the frequency characteristics when the damping portion 70 is absent.

As indicated by the long dashed double-short dashed line in FIG. 6, when the damping portion 70 is absent, the Q-value of the low-pass filter circuit 51 is relatively high. For this reason, the normal-mode noise having a frequency close to the resonance frequency f0 of the low-pass filter circuit 51 is less likely to be reduced by the low-pass filter circuit 51.

On the other hand, since the damping portion 70 is present in the present embodiment, the Q-value of the low-pass filter circuit 51 is low as indicated by the solid line in FIG. 6. For this reason, the normal-mode noise having a frequency close to the resonance frequency f0 of the low-pass filter circuit 51 is reduced by the low-pass filter circuit 51.

As shown in FIG. 6, an allowable value of the gain (attenuation factor) G required based on the vehicle specification is set as an allowable gain Gth. Then, when the frequency of the normal-mode noise is the same as the resonance frequency f0, the Q-value at which the gain G of the low-pass filter circuit 51 becomes the allowable gain Gth is defined as a specific Q-value. In this configuration, the damping portion 70 lowers the Q-value of the low-pass filter circuit 51 to a value below the specific Q-value in the present embodiment. Thus, when the frequency of the normal-mode noise is the same as the resonance frequency f0, the gain G of the low-pass filter circuit 51 is less than (greater than, in terms of the absolute value) the allowable gain Gth. In other words, the damping portion 70 is configured to lower the Q-value of the low-pass filter circuit 51 to a value below the specific Q-value.

The inductance of the normal-mode coil 52 is lowered by the presence of the damping portion 70. For this reason, the resonance frequency f0 of the low-pass filter circuit 51 of the present embodiment is slightly higher than that in the case in which the damping portion 70 is absent.

In particular, as the thickness D1 of the end face covering portions 71, 72 increases, the Q-value due to the damping portion 70 tends to become lower. On the other hand, as the thickness D1 of the end face covering portions 71, 72 increases, the inductance of the normal-mode coil 52 tends to be lower and the resonance frequency f0 and the cutoff frequency fc tends to be higher.

In this respect, in the present embodiment, the thickness D1 of the end face covering portions 71, 72 is determined such that the Q-value of the low-pass filter circuit 51 is lower than the specific Q-value and the cutoff frequency fc is lower than the carrier frequency f1.

The present embodiment, which has been described above, achieves the following advantages.

(1) The in-vehicle motor-driven compressor 10 includes the housing 11, into which refrigerant (fluid) is drawn, the compression portion 12, which is accommodated in the housing 11 and compresses refrigerant, the electric motor 13, which drives the compression portion 12, and the inverter device 30, which drives the electric motor 13. The inverter device 30 is configured to convert DC power to AC power.

The inverter device 30 includes the low-pass filter circuit 51, which reduces the normal-mode noise included in the DC power delivered to the inverter device 30, and the power module 42, which converts the DC power, in which the normal-mode noise has been reduced by the low-pass filter circuit 51, into AC power. The low-pass filter circuit 51 includes the pillar-shaped core 61, which extends in one direction, and the open magnetic circuit type normal-mode coil 52, which has the winding 62 wound around the core 61. The inverter device 30 includes the damping portion 70. The damping portion 70 faces at least one of the two end faces 61a, 61b in the extension direction Y of the core 61 and is arranged at a position where an eddy current is generated by the magnetic force lines produced in the normal-mode coil 52.

With this configuration, the normal-mode noise can be reduced by the low-pass filter circuit 51. Further, since the Q-value of the low-pass filter circuit 51 can be lowered without providing a damping resistor, it is possible to improve the versatility of the in-vehicle motor-driven compressor 10 while limiting an increase in size.

More specifically, as described above, if the Q-value of the low-pass filter circuit 51 is high, the normal-mode noise close to the resonance frequency f0 of the low-pass filter circuit 51 cannot be easily reduced. Therefore, the low-pass filter circuit 51 that has a high Q-value may not function effectively for the normal-mode noise having a frequency close to the resonance frequency f0. This leads to fear that the inverter device 30 may malfunction and the life of the low-pass filter circuit 51 may be reduced. Therefore, there arises a disadvantage that the invention cannot be applied to a vehicle type that generates a normal-mode noise of a frequency close to the resonance frequency f0. In this respect, since the Q-value of the low-pass filter circuit 51 is lowered by the eddy current generated in the damping portion 70 in the present embodiment, the normal-mode noise of a frequency close to the resonance frequency f0 is easily reduced by the low-pass filter circuit 51. This widens the frequency band of the normal-mode noise that can be reduced by the low-pass filter circuit 51, so that the in-vehicle motor-driven compressor 10 can be applied to a wide range of vehicles.

For example, a damping resistor may be connected in series with the normal-mode coil 52 to reduce the Q-value. However, since a damping resistor needs to cope with a relatively high current, its size tends to be large, and the power loss and the amount of generated heat are likely to increase. For this reason, it is necessary to factor in the heat radiation when installing a damping resistor, which may increase the size of the in-vehicle motor-driven compressor 10.

In this respect, in the present embodiment, although eddy current is generated in the damping portion 70, the eddy current is smaller than the current flowing in a damping resistor. Thus, the amount of generated heat of the damping portion 70 tends to be small. The damping portion 70 may be arranged at any position as long as it faces at least one of the two end faces 61a, 61b in the extension direction Y of the core 61 and an eddy current is generated by the magnetic force lines produced in the normal-mode coil 52. This adds to the flexibility of installing position of the damping portion 70, allowing the damping portion 70 to be arranged in a relatively narrow space. Compared to a configuration using a damping resistor, it is easy to reduce the size of the inverter device. Therefore, it is possible to reduce normal-mode noise of a wide frequency band, while limiting increase in the size of the in-vehicle motor-driven compressor.

In particular, in the present embodiment, the damping portion 70 is provided at a position opposed to at least one of the two end faces 61a, 61b in the extension direction Y of the core 61, in which magnetic flux (magnetic flux lines) is likely to concentrate. This enhances the damping effect by the damping portion 70. That is, the Q-value reduction effect is enhanced.

(2) The damping portion 70 includes the two end face covering portions 71, 72, which cover the end faces 61a, 61b in the extension direction Y of the core 61, and the side surface covering portion 73, which covers at least part of the side surface 61c of the core 61 and connects the end face covering portions 71, 72 to each other. With this configuration, at least part of the side surface 61c of the core 61 is covered by the damping portion 70, and a closed loop in which an eddy current flows is formed by the end face covering portions 71, 72 and the side surface covering portion 73, which increases the eddy current generated in the damping portion 70. This further reduces the Q-value of the low-pass filter circuit 51.

(3) The inverter device 30 is arranged between the normal-mode coil 52 and the damping portion 70 and includes the insulating portion 65, which insulates the normal-mode coil 52 from the damping portion 70. With this configuration, it is possible to reduce the Q-value of the low-pass filter circuit 51 while preventing the damping portion 70 and the normal-mode coil 52 from being short-circuited.

(4) The inverter device 30 has the insulating accommodation case 80, which accommodates the normal-mode coil 52 and the damping portion 70. The normal-mode coil 52 and the damping portion 70 are accommodated in the accommodation case 80 in a state where the relative positions are restricted from being changed.

This configuration suppresses changes in the characteristics of the damping portion 70 caused by impacts or vibrations, thereby limiting reduction in the damping effect of the damping portion 70 due to such changes in the characteristics.

More specifically, being mounted in a vehicle, an in-vehicle motor-driven compressor can receive impacts and vibrations. When the damping portion 70 is deformed due to impacts or vibrations, the characteristics of the damping portion 70 with respect to the magnetic flux of the normal-mode coil 52 change and the Q-value of the low-pass filter circuit 51 can become higher than the specific Q-value. In particular, such changes in the characteristics are more likely to occur in a configuration in which the thickness D1 of the end face covering portions 71, 72 is set to be small to prevent the inductance of the normal-mode coil 52 from being excessively low. Further, changes in the characteristics can also occur when the relative positions of the damping portion 70 and the normal-mode coil 52, that is, the positional relationship is changed by impacts or vibrations.

In this respect, in the present embodiment, the accommodation case 80 alleviates impacts and vibrations on the normal-mode coil 52 and the damping portion 70, the changes in the relative positions between the damping portion 70 and the normal-mode coil 52 due to shock and vibration are restricted. This suppresses deformation and changes in the relative position of the damping portion 70 caused by impacts or vibrations, thereby achieving the above described effect of suppressing changes in the characteristics.

In particular, since the accommodation case 80 is made of an insulating material, an eddy current is unlikely to occur in the accommodation case 80. Therefore, the influence on the magnetic flux generated from the normal-mode coil 52 is small. Therefore, while suppressing the influence on the inductance of the normal-mode coil 52 caused by the accommodation case 80, the above-described advantages are ensured.

(5) The power module 42 includes the switching elements Qu1 to Qw2, which are subjected to the PWM control to convert DC power into AC power. The cutoff frequency fc of the low-pass filter circuit 51 is set lower than the carrier frequency f1, which is the frequency of the carrier signal used for the PWM control of the switching elements Qu1 to Qw2. As a result, the ripple noise caused by the switching of the switching element Qu1 to Qw2 is reduced or attenuated by the low-pass filter circuit 51, so that the ripple noise is prevented from flowing out of the in-vehicle motor-driven compressor 10. The ripple noise is normal-mode noise generated in the power module 42. During operation of the PCU 103, the low-pass filter circuit 51 functions to reduce the normal-mode noise flowing into the in-vehicle motor-driven compressor 10, and during operation of the in-vehicle motor-driven compressor 10, the low-pass filter circuit 51 functions to reduce the outflow of the ripple noise.

In view of expanding the frequency band of the normal noise that can be reduced by the low-pass filter circuit 51, the resonance frequency f0 may be set higher than the assumed frequency band of normal-mode noise in order to avoid the occurrence of a resonance phenomenon. In this case, however, the cutoff frequency fc of the low-pass filter circuit 51 also increases, so it would be difficult to lower the cutoff frequency fc below the carrier frequency f1 as described above. On the other hand, increasing the carrier frequency f1 with the increase of the cutoff frequency fc is not preferable because the switching losses of the switching elements Qu1 to Qw2 would be increased.

In this respect, in the present embodiment, since the damping portion 70 is capable of reducing the normal-mode noise of a frequency close to the resonance frequency f0 as described above, it is unnecessary to increase the resonance frequency f0 according to the assumed frequency band of the normal-mode noise. Therefore, the cutoff frequency fc can be lowered below the carrier frequency f1 without excessively increasing the carrier frequency f1. Therefore, it is possible to restrain the ripple noise caused by switching of the switching elements Qu1 to Qw2 from flowing out of the in-vehicle motor-driven compressor 10 while suppressing an increase in the power loss of the power module 42.

The above-described embodiment may be modified as follows.

As shown in FIG. 7, the inverter device 30 may include urging portions 111 provided between the inner surface of the accommodation case 110 and the damping portion 70. The urging portions 111 are provided on the opposite sides in the extension direction Y of the damping portion 70. The urging portions 111 urge the normal-mode coil 52 and the damping portion 70 in the extension direction Y. In other words, the urging portions 111 sandwich the normal-mode coil 52 and the damping portion 70 in the extension direction Y. The unitized body of the normal-mode coil 52, the insulating portion 65, and the damping portion 70 is accommodated in the accommodation case 110 while being detachable by the urging portions 111. Specifically, the unitized body can be easily removed from the accommodation case 110 by being extracted by a force in the direction opposite to the urging force by the urging portions 111. This facilitates replacement of the normal-mode coil 52 and the damping portion 70.

In the above-described modified embodiment, for example, the damping portion 70 may be omitted. In this case, the urging portions 111 are arranged between the normal-mode coil 52 (specifically, the end faces 61a, 61b) and the inner surface of the accommodation case 110, and face the two end faces 61a, 61b in the extension direction Y of the core 61. In this configuration, the urging portions 111 are preferably made of a nonmagnetic conductive material such as aluminum. The urging portions 111 thus function as damping portions. That is, the damping portions may be urging portions that are provided between the inner surface of the accommodation case and the end faces 61a, 61b in the extension direction Y of the core 61 and urge the normal-mode coil 52 in the extension direction Y.

The urging portions 111 do not necessarily need to be provided on both sides of the normal-mode coil 52 (or the damping portion 70), and may be provided only on one side.

The specific configuration of the urging portion 111 is arbitrary. For example, a leaf spring member is may be employed. Further, the urging portions 111 may be provided on the opposite sides of the damping portion 70 in a direction orthogonal to the extension direction Y, and may be configured to urge, or sandwich, the damping portion 70 in a direction orthogonal to the extension direction Y.

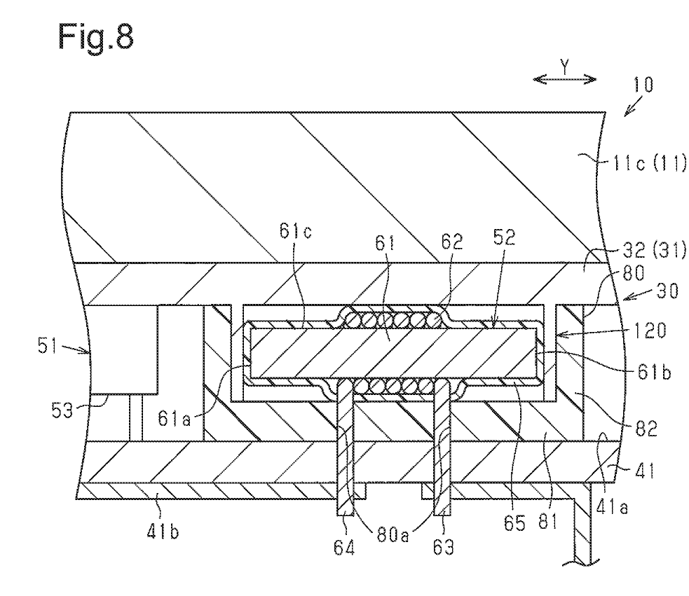

A damping portion 120 shown in FIG. 8 may be employed that is configured to extend upright from the base member 32 and cover the end faces 61a, 61b in the extension direction Y of the core 61. That is, the damping portion may be configured separately from or integrated with the inverter case 31.

The base member 32 may be omitted. In this case, the surface of the damping portion 70 that is adjacent to the mounting wall portion 11c may be in contact with or in the vicinity of the mounting wall portion 11c of the housing 11.

Also, if the base member 32 is not provided, the damping portion may be configured to extend upright from the mounting wall portion 11c and cover at least one of the end faces 61a, 61b in the extension direction Y of the core 61. That is, the damping portion may be integral with the housing 11.

In the embodiment, the thickness D1 of the end face covering portions 71, 72 and the thickness D2 of the side surface covering portion 73 are set to be the same, but it is not limited to this and may be different.

For example, the thickness D1 of the end face covering portions 71, 72 may be greater than the thickness D2 of the side surface covering portion 73. In this case, the damping effect by the damping portion 70 is improved. Further, by making the thickness D2 of the side surface covering portion 73 less than the thickness D1 of the end face covering portions 71, 72, miniaturization in the opposing direction of the circuit board 41 and the base member 32 is possible.

In contrast, the thickness D2 of the side surface covering portion 73 may be greater than the thickness D1 of the end face covering portions 71, 72. In this case, the strength of the damping portion 70 is improved by an amount corresponding to the increase in the thickness D2 of the side surface covering portion 73, while limiting reduction in the inductance of the normal-mode coil 52.

The core 61 is not limited to a columnar shape as long as it is shaped as a pillar extending in one direction. For example, the core 61 may be shaped as a prism, or it may have an I-shape in which the opposite ends in the extension direction Y are larger in diameter than the central portion. A protrusion or a recess may be formed on the end faces 61a, 61b or the side surface 61c of the core 61. In other words, the core 61 may have any shape as long as it forms an open magnetic circuit.

The specific configuration of the insulating portion 65 is arbitrary as long as it can insulate the normal-mode coil 52 from the damping portion 70. For example, the insulating portion 65 may be an insulating coating formed on the inner surface of the damping portion 70 or the surface of the normal-mode coil 52.

The shape of the damping portion 70 is not limited to that of the embodiment. For example, the damping portion 70 may have a shape with an opening facing the mounting wall portion 11c. In this case, the side surface covering portion 73 covers part of the side surface 61c of the core 61. That is, the side surface covering portion 73 may be configured to cover part of the side surface 61c of the core 61. In addition, the side surface covering portion 73 is not limited to a rectangular tubular shape, but may be cylindrical.

The damping portion 70 does not need to have a completely closed box shape. For example, the damping portion 70 may have a slit extending in the extension direction Y or a through-hole extending in the radial direction of the core 61.

At least part of the damping portion 70 may be a mesh portion, recesses, embossed portions, or punched holes.

The end face covering portions 71, 72 may cover parts of the end faces 61a, 61b in the extension direction Y of the core 61. Either one of the end face covering portions 71 and 72 may be omitted. Also, the side surface covering portion 73 may be omitted.

Through-holes may be formed in the end face covering portions 71, 72, and the terminals 63, 64 may extend in the extension direction Y and are inserted through the through-holes. Even in this case, it can be said that the end face covering portions 71, 72 cover the end faces 61a, 61b in the extension direction Y of the core 61.

The positions of the normal-mode coil 52 and the damping portion 70 are arbitrary as long as they are within the inverter case 31. For example, the normal-mode coil 52 and the damping portion 70 do not need to be arranged between the board surface 41a of the circuit board 41 and the base member 32, but may be arranged at positions protruding laterally with respect to the circuit board 41 as viewed in the direction in which the board surface 41a and the base member 32 are opposed to each other.

The normal-mode coil 52 may be arranged between the board surface 41a and the base member 32 in a state of being extending upright with respect to the circuit board 41 so that the extension direction Y and the opposing direction coincide with each other.

The normal-mode coil 52 and the damping portion 70 may be accommodated in the accommodation case 80 in a state where the relative positions are changeable. For example, there may be a gap between the damping portion 70 and the accommodation case 80 (specifically, the upright wall portion 82).

The concrete shape of the accommodation case 80 is arbitrary. For example, the bottom portion 81 may be omitted, or part of the upright wall portion 82 may be omitted. The part of the upright wall portion 82 is either a portion facing the side surface covering portion 73 or a portion facing the end face covering portions 71, 72.

The accommodation case may be made of a metal having conductivity. In this case, the accommodation case and the damping portion 70 are preferably short-circuited with each other.

The accommodation case 80 may be omitted.

The boost converter 104 may be omitted. In this case, the normal-mode noise is, for example, noise generated by the switching frequency of the switching elements of the vehicle-driving inverter.

The housing 11 and the inverter case 31 may be made of different materials from that of the damping portion 70.

For example, in the configuration in which a loop-shaped rib extends upright from the mounting wall portion 11c of the housing 11, the inverter case may be replaced by a plate-shaped inverter covering member in a state of abutting against the rib. In this case, the mounting wall portion 11c of the housing 11, the rib, and the inverter covering member preferably form an accommodating chamber that accommodates various kinds of components such as the circuit board 41, the power module 42, and the low-pass filter circuit 51. In short, the concrete configuration for defining the accommodating chamber is arbitrary.

The in-vehicle motor-driven compressor 10 of the above illustrated embodiment is a so-called inline type. However, a camel back type may be employed, in which the inverter device 30 is arranged outward of the housing 11 in the radial direction of the rotary shaft 21. In short, the position of the inverter device 30 is arbitrary.

In the above illustrated embodiment, the in-vehicle motor-driven compressor 10 is used in the in-vehicle air conditioner 100. However, the in-vehicle motor-driven compressor 10 may be used in other apparatuses. For example, if the vehicle is a fuel cell vehicle, the in-vehicle motor-driven compressor 10 may be used in the air supplying device that supplies air to the fuel cell. That is, the fluid to be compressed is not limited to refrigerant, but may be any fluid such as air.

The in-vehicle device is not limited to the PCU 103, but may be any device that includes switching elements, which are periodically turned on and off.

For example, the in-vehicle devices may include an inverter that is separately provided from the inverter device 30.

The specific circuit configuration of the low-pass filter circuit 51 is not limited to the one according to the above illustrated embodiment. For example, the low-pass filter circuit 51 may be of a π-type or T-type. That is, the number of the normal-mode coils 52 may be one or more, and the number of the capacitor 53 may be one or more.

The above described modifications may be used in combination or applied to the above illustrated embodiment as necessary.

Therefore, the present examples and embodiments are to be considered as illustrative and not restrictive and the invention is not to be limited to the details given herein, but may be modified within the scope and equivalence of the appended claims.

1. An in-vehicle motor-driven compressor comprising:
a housing, into which a fluid is drawn;
a compression portion, which is accommodated in the housing and compresses the fluid;
an electric motor, which drives the compression portion; and
an inverter device, which drives the electric motor and converts DC power into AC power, wherein
the inverter device includes
a low-pass filter circuit, which is configured to reduce normal-mode noise included in the DC power, and
an inverter circuit, which converts the DC power, of which the normal-mode noise has been reduced by the low-pass filter circuit, into the AC power,
the low-pass filter circuit includes a normal-mode coil, which includes a pillar-shaped core extending in one direction and a winding wound around the core and forms an open magnetic circuit,
the core has two end faces in an extension direction of the core,
the inverter device includes a damping portion, and
the damping portion is arranged at a position where the damping portion is opposed to at least one of the two end faces of the core and an eddy current is generated by magnetic force lines produced in the normal-mode coil.

2. The in-vehicle motor-driven compressor according to claim 1, wherein
the inverter device includes an insulating portion, which is arranged between the normal-mode coil and the damping portion, and
the insulating portion insulates the normal-mode coil from the damping portion.

3. The in-vehicle motor-driven compressor according to claim 1, wherein
the inverter device includes an insulating accommodation case, which accommodates the normal mode coil and the damping portion, and
the normal-mode coil and the damping portion are accommodated in the accommodation case in a state where relative positions thereof are restricted from being changed.

4. The in-vehicle motor-driven compressor according to claim 3, wherein
the inverter device further includes an urging portion, which is arranged between an inner surface of the accommodation case and the damping portion,
the urging portion is configured to urge the normal-mode coil and the damping portion, and
the normal-mode coil and the damping portion are accommodated in the accommodation case while being detachable by the urging portion.

5. The in-vehicle motor-driven compressor according to claim 1, wherein the damping portion includes
a pair of end face covering portions, which covers the two end faces in the extension direction of the core, and
a side surface covering portion, which covers at least part of a side surface of the core and connects the end face covering portions to each other.

6. The in-vehicle motor-driven compressor according to claim 5, wherein
the end face covering portions are shaped like plates that are arranged such that a thickness direction of the end face covering portions coincides with the extension direction of the core,
the side surface covering portion is a tubular wall portion that covers the side surface of the core, and
a thickness of the end face covering portions is greater than a thickness of the side surface covering portion.

7. The in-vehicle motor-driven compressor according to claim 5, wherein
the inverter device includes an insulating accommodation case, which accommodates the normal mode coil and the damping portion,
the normal-mode coil and the damping portion are accommodated in the accommodation case in a state where relative positions thereof are restricted from being changed,
the end face covering portions are shaped like plates that are arranged such that a thickness direction of the end face covering portions coincides with the extension direction of the core,
the accommodation case includes a bottom portion and an upright wall portion, which extends upright from the bottom portion,
the upright wall portion and the end face covering portions are opposed to each other, and
a thickness of the end face covering portions is less than a thickness of the upright wall portion.
